(19) United States
(12) Patent Application Publication
(10) Pub. No.: US 2026/0305363 A1
(43) Pub. Date: Oct. 1, 2026

(54) BGA-TYPE RADIO-FREQUENCY DEVICE

(71) Applicant: STMicroelectronics International N.V., Geneva (CH)

(72) Inventors: Vipin VELAYUDHAN, Grenoble (FR); Florian PERMINJAT, Saint Romans (FR); Jerome LOPEZ, Saint Jean De Moirans (FR); David AUCHERE, Meylan (FR); Laurent SCHWARTZ, La Buisse (FR)

(73) Assignee: STMicroelectronics International N.V., Geneva (CH)

(21) Appl. No.: 19/631,119

(22) Filed: Mar. 27, 2026

(30) Foreign Application Priority Data
Mar. 28, 2025 (FR) FR2503207

(51) Int. Cl. H10W 44/20; H10W 70/68; H10W 90/00

(52) U.S. Cl. CPC H10W 44/234; H10W 70/681; H10W 90/724

(57) ABSTRACT

A radio frequency chip is mounted on a first main surface of a laminated substrate that includes a vertical RF feedthrough to a second main surface of the laminated substrate. A plated part is bonded to the second main surface of the substrate opposite the vertical RF feedthrough. The laminated substrate is mounted to a printed circuit board which includes a through hole. The plated part is positioned extending at least partially into the through hole. The plated part includes an element made of a dielectric material with side walls at least partially covered by a coating made of electrically-conductive material.

### PRIORITY CLAIM

This application claims the priority benefit of French Application for Patent No. FR2503207, filed on Mar. 28, 2025, the content of which is hereby incorporated by reference in its entirety to the maximum extent allowable by law.

### TECHNICAL FIELD

The present disclosure generally concerns substrates for an electronic device transmitting and/or receiving radio frequency signals. Such devices have applications, for example, in the field of automotive radars, for example in automotive advanced driver assistance systems (ADAS).

### BACKGROUND

Typically, in ADAS devices, radio frequency signals (76 GHz to 81 GHz, for example) are transmitted and received by antennas. The transmission and reception delays are used to calculate the distance of the object. Then, a plurality of radars with image processing algorithms are used to identify the shape of the object. This type of system or function is called radio detection and ranging (RADAR).

Devices can have a plurality of architectures. In devices having a launcher-on-package (LoP) architecture, a chip is placed on the upper surface of a substrate of ball grid array (BGA) type, itself arranged on a printed circuit board (PCB) provided with plated through holes (PTH). An antenna guide module comprising an antenna and a waveguide is placed on the other side of the PCB.

Thus, signals can be routed from the chip to the antenna module via the PCB.

The dimensions of the through holes of the PCB, and thus those of the PCB, depend on the cut-off frequency of the RF waveguide.

Now, in the case of a launcher-on-package architecture, it is necessary to integrate a plurality of launchers in a single package.

There thus exists a need to decrease the dimensions of the through holes of the printed circuits boards of RF devices without modifying cut-off frequencies.

There is a need to overcome all or part of the disadvantages of known devices.

### SUMMARY

An embodiment provides a radio frequency device, for example of BGA type, comprising a radio frequency chip mounted on a first main surface of a laminated substrate comprising a vertical RF feedthrough, a plated part being bonded to a second main surface of the substrate opposite the vertical RF feedthrough, the plated part being configured to be mounted opposite a through hole of a printed circuit board, and preferably to be inserted into the through hole of the printed circuit board; the plated part comprising an element made of a dielectric material, having its side walls partially, or even totally, covered by a coating made of electrically-conductive material.

According to an embodiment, the plated part is bonded to the second main surface of the laminated substrate by means of a layer of adhesive, in particular an epoxy adhesive.

According to an embodiment, the dielectric material has a dielectric permittivity greater than or equal to 2 and, preferably, smaller than 10.

According to an embodiment, the dielectric material is glass.

According to an embodiment, the coating of the plated part is made of metal or of a metal alloy, preferably of silver.

According to an embodiment, a second main surface (bottom surface) of the plated part is positioned opposite the through hole at the level of the first surface of the printed circuit board or in the through hole between the first surface and the second surface of the printed circuit board, the plated part being inserted into the through hole down to a depth, preferably, of at least 0.3 mm.

According to an embodiment, the side walls of the plated part have a height of at least 50 µm, and preferably at least 100 µm, for example 300 µm.

Another embodiment provides a system of transmission/reception of a radio frequency signal, comprising a radio frequency device as previously defined, positioned on a first surface of a printed circuit board, an antenna module being arranged on a second surface of the printed circuit board, and being coupled to the radio frequency device by means of a through hole of the printed circuit board, the plated part being arranged opposite the through hole of the printed circuit board, and preferably being partially inserted into the through hole of the printed circuit board.

According to an embodiment, the through hole is an oblong hole having its largest dimension in the range from 1 mm to 3 mm, preferably from 1.1 mm to 2.54 mm, and its smallest dimension in the range from 0.4 mm to 1.5 mm, preferably from 0.55 mm to 1.1 mm.

According to an embodiment, a layer of electrically-insulating polymer is arranged between the laminated substrate and the printed circuit board, around the plated part.

According to an embodiment, the through hole is filled with an electrically-insulating material, for example an epoxy resin.

Another embodiment provides a method of manufacturing a radio frequency device such as previously defined comprising a step during which the plated part is bonded to the laminated substrate, preferably by means of a layer of adhesive.

Another embodiment provides a method of manufacturing a system for transmitting/receiving a radio frequency signal such as previously defined, comprising a step during which a radio frequency device such as previously defined is assembled, for example by soldering, on the first surface of the printed circuit board, the antenna module being arranged on the second surface of the printed circuit board, and being coupled to the radio frequency package by means of the hole extending through the printed circuit board, the plated part being arranged opposite the through hole of the printed circuit board, and preferably being partially inserted into the through hole of the printed circuit board.

According to an embodiment, after the assembly of the radio frequency device with the printed circuit board, the method comprises a step during which a layer of electrically-insulating polymer is injected between the laminated substrate and the printed circuit board, around the plated part, and preferably, a subsequent step during which an electrically-insulating material, for example, an epoxy resin, is injected into the through hole.

Another embodiment provides a method of manufacturing a plated part comprising the following steps: providing an element made of a dielectric material, preferably of glass; and depositing a coating made of electrically-conductive material, preferably metal, for example, silver, on the side walls of the element made of dielectric material, for example by sputtering, inkjet, or PVD.

According to an embodiment, the element made of dielectric material is locally covered by a protective element during the deposition, whereby the side walls of the element are partially coated with the electrically-conductive material.

### BRIEF DESCRIPTION OF THE DRAWINGS

The foregoing features and advantages, as well as others, will be described in detail in the rest of the disclosure of specific embodiments given as an illustration and not limitation with reference to the accompanying drawings, in which:

FIGS. 1, 2, and 3 are simplified representations, in cross-section and side view, of embodiments of a radio frequency signal transmit/receive system;

FIGS. 4A and 4B are simplified representations of a cross-section and side view of embodiments of different laminated substrates to which a plated part has been bonded;

FIGS. 5A and 5B are simplified representations in top view of the fourth metal layer of the laminated substrates respectively shown in FIGS. 4A and 4B;

FIG. 6 is a simplified representation, in cross-section and top view, of an oblong through hole of a printed circuit board;

FIG. 7 is a graph showing the length a of an oblong through hole as a function of cut-off frequency for different elements (air, FR4, and glass) positioned in the oblong hole;

FIG. 8 shows different successive steps (views A, B, C, D, and E) of a method of manufacturing a plated dielectric part;

FIG. 9 shows different successive steps (views A, B, C, D, and E) of a method of manufacturing a plated dielectric part;

FIG. 10 shows different successive steps (views A, B, and C) of a method of manufacturing a plated dielectric part.

### DETAILED DESCRIPTION

The drawings are not necessarily to a uniform scale so as to make them easier to read.

The same elements have been designated by the same the same elements have been designated by the same references in the various figures. In particular, structural and/or functional elements common to the different embodiments may have the same references and may have identical structural, dimensional and material properties.

For the sake of clarity, only those steps and elements that are useful for understanding the described embodiments have been shown and are described in detail. In particular, the applications of the described embodiments and the uses of the antenna are not described.

Unless specified otherwise, when reference is made to elements connected together, this signifies a direct connection without any intermediate elements other than conductors, and when reference is made to two elements coupled together, this signifies that these two elements can be connected or they can be coupled via one or more other elements. Further, the term "coupled" is used to designate an electrical coupling between elements.

In the following description, where reference is made to absolute position qualifiers, such as the terms "front", "back", "top", "bottom", "left", "right", etc., or relative position qualifiers, such as the terms "top", "bottom", "upper", "lower", etc., or orientation qualifiers, such as "horizontal", "vertical", etc., reference is made unless otherwise specified to the orientation of the drawings. In particular, the term vertical propagation or vertical RF feedthrough refers to a RF propagation or feedthrough along the z axis.

Unless specified otherwise, the expressions "about", "approximately", "substantially", and "in the order of" signify plus or minus 10%, preferably of plus or minus 5%.

By between X and Y, there is meant that limits X and Y are included.

The package which will be described hereafter can be used for radio frequency applications. By radio frequency (RF), there is meant frequencies between 3 kHz and 300 GHz, and more particularly frequencies between 76 GHz and 81 GHz, for the manufacturing of ADAS-type automotive radars. Even though the description mentions, in particular, frequencies in the range from 76 GHz to 81 GHz, other frequencies may be used for other devices using other radio frequencies. Applications may also concern microwaves or millimeter waves.

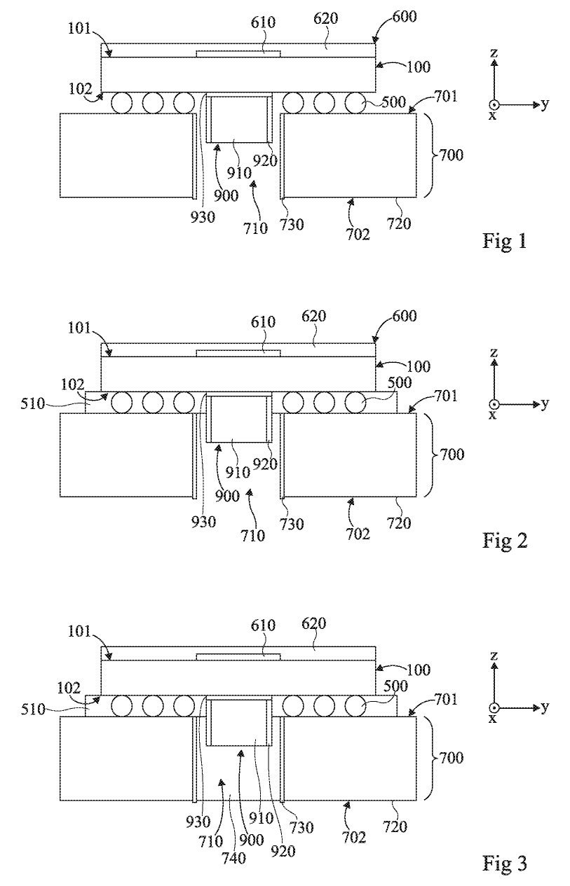

As shown in FIGS. 1, 2, and 3, the radio frequency device comprises a laminated substrate 100 and a package 600 comprising at least one electronic component 610 and, in particular, at least one radio frequency component 610, molded in an insulating material 620 (or molding compound), such as a polymer or a resin. The RF device also comprises a plated part 900 bonded to the lower surface 102 of laminated substrate 100. When printed circuit board 700 is assembled to laminated substrate 100, plated part 900 is positioned opposite the through hole 710 (or via) of printed circuit board 700 (PCB). Preferably, plated part 900 penetrates through hole 710.

Plated part 900 is made of glass or of any other dielectric material with a low loss and a high dielectric permittivity (typically with εr greater than or equal to 2 and smaller than 10). Plated part 900 enables to decrease the size of the through hole 710 of PCB 700 while keeping the same cut-off frequencies.

The various elements of the RF device will now be described with reference to FIGS. 1, 2, 3, 4A, 4B, 5A, 5B, and 6.

In the various drawings, laminated substrate 100 is a ball grid array (BGA) substrate. However, it could also be a land grid array (LGA) substrate or a pin grid array (PGA) substrate.

Substrate 100 comprises a first main surface 101 and a second main surface 102.

The first main surface 101 may be connected to a chip or a plurality of chips and the second main surface 102 may be assembled to a printed circuit board (PCB) 700. The second surface 102 of substrate 100 is covered with an array of balls 500. Balls 500 are connection pads enabling to bond substrate 100 to an external device 700, for example a printed circuit board.

Substrate 100 preferably comprises at least four metal layers 110, 120, 130, 140 from the first main surface 101 to the second main surface 102. The first metal layer 110 is located on the side of the first surface 101. The fourth metal layer 140 is on the side of the second surface 102.

A substrate with four metal layers will more particularly be described, but there could be less than four or also more than four metal layers (five or six, for example), for example by adding intermediate metal layers between the above-mentioned metal layers.

Metal layers 110, 120, 130, 140 may be made of a metal or of a metal alloy. They are for example made of a material selected from among gold, copper, aluminum, an alloy of copper and aluminum. Metal layers 110, 120, 130, 140 have, for example, a thickness in the range from 5 to 50 µm, preferably from 5 to 35 µm, and even more preferably from 15 to 25 µm. Metal layers 110, 120, 130, 140 have, for example, a 40-µm thickness.

For example, metal layers 110, 120, 130, 140 are metal foils, particularly copper foils.

The various metal layers 110, 120, 130, 140 are positioned one on top of the other. Metal layers 110, 120, 130, 140 are separated from one another by dielectric layers 210, 220, 230 in order to insulate them from one another. Each metal layer has a thickness, for example, in the range from 20 to 400 µm.

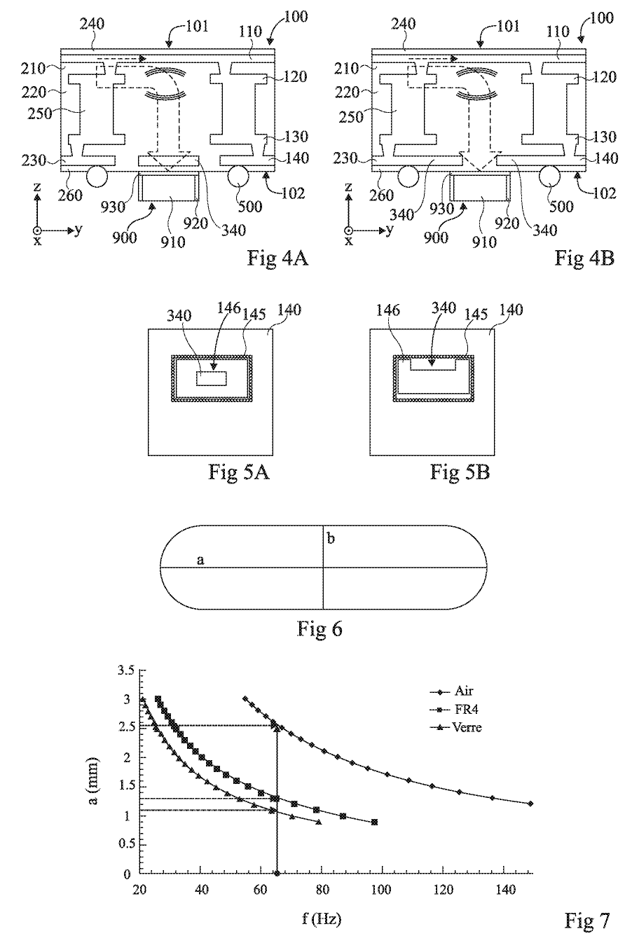

An alternation of metal layers 110, 120, 130, 140 and of dielectric layers 210, 220, 230 is obtained (FIGS. 4A and 4B). The stack of laminated substrate 100 successively comprises from the first main surface 101 to the second main surface 102: the first metal layer 110; the first dielectric layer 210; the second metal layer 120; the second dielectric layer 220; the third metal layer 130; the third dielectric layer 230; and the fourth metal layer 140.

Additional dielectric layers 240, 260 may be arranged on either side of the previously-described stack in order to insulate metal layers 110, 140.

The dielectric layers 210, 220, 230, 240, 260 are made of a material allowing the transmission of the electromagnetic field. They have, for example, a dielectric constant greater than 2. The dielectric layers 210, 220, 230, 240, 260 are, for example, made of a so-called prepreg material. By prepreg material, there is meant a composite material comprising a thermoplastic polymer or a thermosetting resin and fillers, for example glass fibers. The dielectric layers may also be made of ABF (referred to in the art as Ajinomoto's Insulation film^{®}).

The second dielectric layer 220 forms the core of the stack and may be made of a different material than the other dielectric layers 210, 230, 240, 260. It is, for example, made of a resin that may contain fibers, in particular glass fibers, for example, of an epoxy resin containing glass fibers. It may be, for example, made of a material having a dielectric constant greater than 2. For example, it is made of a Flame Retardant 4 (FR-4) material. The second dielectric layer 220 may have a thickness in the range from 100 to 150 µm.

Slots are formed in the metal layers 110, 120, 130, 140 of each level.

At least the slots of the second, third, and fourth layers 120, 130, 140 are positioned one above the other along the z axis, so as to form a vertical RF feedthrough and be able to transmit radio frequencies from chip 610 to PCB 700. The vertical RF feedthrough thus extends through the different levels of laminated BGA substrate 100. This vertical RF feedthrough maximizes the bandwidth without increasing the insertion loss or size.

The size of the slot determines the frequency and the field of propagation to the waveguide (TE10).

The slots may be partially or totally filled with the dielectric material of the lower or upper dielectric layer.

Within the slot of the first metal layer 110, a transmission line (also called feed line; not shown in the drawings) extends. The transmission line is arranged coplanar with the first metal layer 110 (that is, they are in the same x-y plane). Transmission line is, for example, intended to be connected to chip 610. Transmission line is made of metal. It may, for example, be made of copper, aluminum, or gold. Transmission line comprises a longitudinal element, such as a wire or a band, and an end. The end of the transmission line may have a square, rectangular, or triangular shape. The length and the width of the transmission line depend on frequency.

The first metal layer 110 and transmission line form a first level of substrate 100 and play the role of impedance matching. The impedance is modified: there is a transition from a lower impedance in the transmission line to a higher impedance in the waveguide. The orientation of the signal is also changed by 90° between the first slot and the second slot 126 (represented by arrows in FIGS. 4A, 4B), allowing the signal to propagate vertically through the next slots.

Preferably, at least one slot selected from among the second slot, the third slot, and the fourth slot comprises a frequency matching element 340. Preferably, at least the fourth slot 146 comprises a matching element 340 (such as for example shown in FIGS. 4A, 4B, 5A, and 5B). The frequency matching elements 340 are configured to channel the electromagnetic signal into the slots.

In the drawings, a single matching element 340 is shown, but it is however possible to have a matching element positioned in a plurality of slots of a same substrate 100.

The frequency matching elements may have different dimensions. Depending on the desired characteristics, the frequency matching elements may be positioned at the center of the slot or on the edges of the slot and/or have different shapes. The matching elements are not necessarily aligned with one another.

According to an embodiment, the frequency matching element 340 may be a patch isolated from the edges of slot 146 by a gap (FIGS. 4A, 5A). Patch frequency matching element 340 is, for example, a metal plate. For example, it is a copper plate. The patch may be made of a same material as the metal layer. The patches are preferably made of a conductive material, preferably of a metal, for example of copper, aluminum, an alloy of copper and aluminum, or gold. The patches are, for example, rectangular or square. They could also be circular. The patches may have the same thickness as the metal layers, or an identical thickness to within 10% or even 5%.

According to another embodiment, impedance matching element 340 may be a portion of the metal layer which protrudes into the slot (FIG. 4B, 5B). In other words, part of the metal layer extends in the slot and forms an overhang or prominence in slot 146. The protruding portion forms an inner extension of the metal plate at an edge of the slot or a corner of the slot. The projecting portions are, for example, rectangular or square. The projecting portions have the same thickness as the metal layers. The irregular shapes of the projecting portions and/or of the slot enable to match the frequency and the bandwidth.

These embodiments may be combined. It is possible, within a same device, to use patches for one or more levels and protruding portions for one or more levels.

The stack also comprises interlayer metal vias 250 formed through part of the layers of the stack so as to be able to connect different metal layers 110, 120, 130, 140 to one another. Interlayer metal vias 250 may be stacked one on top of the other or offset from one another.

Each slot may be surrounded by a row of vias to help confine electromagnetic waves within the slots and/or prevent signal leakages. The different rows of vias are positioned one on top of the other along the z axis. It is possible to have one row of vias or a plurality of rows of vias per metal layer 110, 120, 130, 140. For example, in FIGS. 5A and 5B, only one row of vias 145 is shown around the fourth slot 146. These slots also have a certain impedance and a certain operating frequency.

Such a substrate results in the obtaining of a wide-band, low-loss RF feedthrough at the desired frequencies. This stack enables to adapt to the entire desired radio frequency band (in particular, 76 GHz - 81 GHz).

Moreover, with such a substrate 100, it is possible to obtain a bandwidth a little wider than the frequency range conventionally used in automotive radars (76GHz - 81GHz), which enables to be less sensitive to manufacturing. It is possible to size the slots and the matching elements as a function of the working frequency and/or of the substrate. Frequencies in the range from 24.0 to 24.25 GHz may also be used.

This compact, high-performance feedthrough can be formed by means of a standard technology of laminate substrate 100. Costs are thus decreased.

The RF feedthrough is configured to be mounted opposite a through hole 710 of a printed circuit board 700.

The thickness of substrate 100 is, for example, in the range from 100 to 900 µm, for example from 100 to 200 µm, for example in the order of 150 µm, or from 200 to 300 µm.

In addition to the previously-described substrate 100, the radio frequency device also comprises an RF package 600. RF package 600 comprises a radio frequency component 610 and a molding compound 620. RF component 610 is a component capable of transmitting and receiving specific radio frequency signals. In particular, radio frequency component 610 is a radio frequency chip 610.

Chip 610 has, on its front surface, connection pads covered by metallized bumps (not shown). The metallized bumps are, for example, made of tin or of a tin-based alloy.

Chip 610 is directly mounted on laminate substrate 100, the bumps of chip 610 are oriented towards the side of the first surface 101 of substrate 100 ('flip-chip'). Chip 610 is connected to substrate 100 by its bumps. It could be bonded to the substrate by wire bonding.

Chip 610 is connected to the transmission line of substrate 100, for example by means of microstrips.

The device further comprises a plated part 900.

Plated part 900 comprises a part (or element) 910 made of a dielectric material and an electrically-conductive coating 920.

Element 910 is, preferably, a monoblock.

Element 910 may have different shapes: it may be, for example, an oblong, cylindrical, parallelepipedal or cubic shape. Preferably, the shape is oblong like the shape of the through holes 710 of printed circuit board 700. The through holes 710 are plated.

The dielectric material has, for example, a dielectric permittivity greater than or equal to 2 and, preferably, lower than 10, even more preferably lower than 8 or even lower than 7. The dielectric material is, for example, selected from among: glass, an epoxy resin, a polyimide, a polytetrafluoroethylene, a poly(p-phenylene oxide) (PPO), a bismaleimide-triazine resin (BT), FR-4, or also a composite formed of one or more of the above-mentioned materials (for example, a composite formed of an epoxy resin and of glass fibers).

Plated part 900 comprises a first main surface (or upper surface) intended to be in contact with laminated substrate 100, a second main surface (or lower surface) intended to be positioned opposite the through hole (via) 710 extending through printed circuit board 700 and, preferably, in the through hole (via) 710 extending through printed circuit board 700, and lateral surfaces. The main surfaces are parallel or substantially parallel to each other.

The main surfaces have dimensions selected so as to allow the insertion of plated part 900 into the through hole 710 of printed circuit board 700.

The lateral surfaces have a height selected so that the second main surface (lower surface) of plated part 900 is positioned opposite through hole 710 at the level of the first surface 701 of the printed circuit board 700 or in the through hole 710 between the first surface 701 and the second surface 702 of printed circuit board 700. The lateral surfaces have, for example, a height of at least 50 µm, preferably at least 100 µm, for example 300 µm. The height of the lateral surfaces can be measured along the z axis in FIGS. 1-3 and 4A and 4B.

The dimensions of part 900 are selected so as to cover impedance matching element 340 (in other words, the surface area of the main surfaces of plated part 900 is greater than or equal to that of matching element 340).

The lateral surfaces are partially or totally covered by a coating 920. When coating 920 partially covers the lateral surfaces, it covers them from the upper surface. For example, it covers at least 40%, preferably at least 60%, and even more preferably between 60% and 80% of the height of the lateral surfaces.

Preferably, the side walls are totally covered by coating 920.

Coating 920 is made of an electrically-conductive material. It is, for example, made of metal or of a metal alloy. Preferably, it is made of silver or copper. It has a thickness, for example, in the range from 100 nm to 10 µm, for example, 2 µm.

The resistivity of coating 920 is for example 3 µohm.cm.

Plated dielectric part 900 is bonded to laminated substrate 100, and more particularly to the second surface 102 of laminated substrate 100.

Plated dielectric part 900 is preferably bonded to laminated substrate 100 by an adhesive bonding layer 930. The adhesive may be an epoxy adhesive.

The RF devices may be adapted to a variety of substrate technologies, which include RF and mmW waveguides, connectors or any other components.

Such an RF device can be used in an RF signal transmit/receive system.

The RF signal transmit/receive system comprises, for example, the previously-described radio frequency device, a printed circuit board 700, and an antenna module or another waveguide.

Printed circuit board 700 comprises plated through holes (PTH) 710 extending from the first surface 701 to the second surface 702 of printed circuit board 700. The side walls 730 of through holes 710 confine electromagnetic waves. The upper and lower surfaces of substrate 700 may also be plated to form the waveguide. Holes 710 are, for example, oblong holes (FIG. 6). The largest dimension 'a' of the oblong hole is, for example, in the range from 1 to 3 mm, and preferably from 1.1 to 2.54 mm. It is, for example, 2.54 mm or 1.2 mm. The smallest dimension 'b' of the oblong hole is, for example, in the range from 0.4 to 1.5 mm, preferably from 0.45 to 1.1 mm, and even more preferably from 0.55 to 1.1 mm. It is, for example, 1.1 mm or 0.55 mm. Preferably, it is smaller than or equal to 0.55 mm, for example 0.45 mm. Dimensions 'a' and 'b' are measured along the x or y axis.

The length of the plated part corresponds to the dimension in the direction of the largest dimension 'a' of the hole. The width of the plated part corresponds to the dimension in the direction of the smallest dimension 'b' of the hole. The length and the width of the plated part correspond, for example, to between 60% and 80% of the largest and of the smallest dimension of the hole, respectively.

Plated part 900 has, for example, a length in the range from 0.6 to 2.4 mm, preferably from 0.66 to 2.03 mm. Plated part 900 has, for example, a width in the range from 0.24 to 1.2 mm, preferably from 0.33 to 0.99 mm.

Laminated substrate 100 is bonded to the first surface 701 of printed circuit board 700. In particular, the balls 500 of BGA substrate 100 are soldered to printed circuit board 700. The balls 500 of the BGA are, for example, made of tin or of a tin alloy, such as SAC (alloy of tin, silver, and copper). Part of the balls 500 of the BGA plays the role of a short waveguide to transmit the signal to PCB 700.

Once the assembly has been performed, plated dielectric part 900 faces the through hole 710 of printed circuit board 700. The second main surface of plated dielectric part 900 may be flush with the upper surface 701 of printed circuit board 700. Preferably, plated dielectric part 900 is inserted into through hole 710, in such a way that the second main surface of plated part 900 is positioned at the level of through hole 710, between the first surface 701 and the second surface of printed circuit board 700. The penetration depth depends on the hole dimensions. For example, it penetrates through hole 710 down to a depth of at least 0.3 mm. For a hole having a 1.5-mm depth, it preferably penetrates down to a depth in the range from 0.3 to 1.5 mm, and even more preferably from 0.3 to 1.25 mm. The depth is measured along the z axis.

For example, the surface area of the main surfaces of plated dielectric part 900 corresponds to at least 60% and preferably at least 80% of the surface area of through hole 710. The distance between plated dielectric part 900 and the walls of through hole 710 is selected so as not to create a physical and electrical contact between the coating 920 of plated part 900 and the side walls 730 of through hole 710. The distance between plated dielectric part 900 and the walls of through hole 710 is, for example, in the range from 50 to 300 µm, preferably from 100 to 200 µm.

A layer of electrically-insulating polymer 510 ('underfill') may be positioned between laminated substrate 100 and printed circuit board 700 (FIG. 2). It improves the electrical insulation of the connection pads 500 of laminated substrate 100. It may be formed by injection.

The layer of electrically-insulating polymer 510 is in contact with plated dielectric part 900, and more particularly with a portion (the upper portion) of the lateral surfaces of said part 900.

According to an alternative embodiment, in addition to polymer layer 510, an electrically-insulating filling material 740, for example an epoxy resin, may be positioned in through hole 710 (FIG. 3). It is in contact with at least the second surface of plated dielectric part 900 and, preferably, with part of the lateral surfaces of plated dielectric part 900. Preferably, plated dielectric part 900 and electrically-insulating filling material 740 fill through hole 710. It may be formed by injection.

A plurality of RF devices may be positioned on the same printed circuit board 700, and more particularly on the first surface 701 of printed circuit board 700.

The antenna module (not shown) is arranged on a second surface 702 of printed circuit board 700. The antenna module comprises a substrate having a waveguide and antennas formed therein.

The antenna module is coupled to the radio frequency device by means of the holes 710 extending through printed circuit board 720. The signal is transmitted continuously from chip 610 to PCB700, and then to the waveguide and to the antenna of the antenna module.

The radio frequency signal is thus routed, from radio frequency component 610, through BGA substrate 100, due to the vertical RF feedthrough, and then through plated part 900 all the way to the holes 710 formed in printed circuit board 700, and on to the antenna module. Any other RF module could also be bonded to the waveguide.

The method of manufacturing a plated dielectric part 900, and in particular a plated glass part, will now be described.

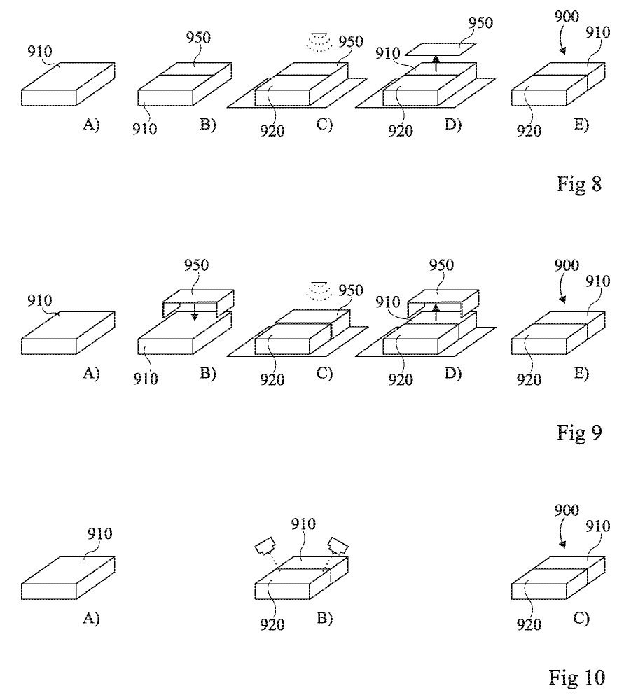

The method of manufacturing a plated part 900 comprises the following steps: providing a glass substrate, and positioning it on a dicing frame; cutting the glass substrate into a plurality of parts 910 ('dicing'); preferably rinsing parts 900, for example with water; preferably, performing a surface activation of parts 900, for example, with a plasma; plating the side walls of parts 900, to form a coating 920; preferably carrying out a post-treatment (heat treatment and/or photonic treatment), see view A of FIGS. 8, 9 and 10.

Non-exhaustively, the glass substrate dicing step may be carried out by mechanical cutting (for example by means of a carbide tool), by waterjet cutting, by saw cutting, by laser cutting, by stealth dicing, followed by a step of expansion of the cutting support, by laser-induced deep etching (LIDE), by nano-perforation (the surface modifications are performed by laser) and fracture.

With such methods, a number of shapes of parts 900 can be obtained.

The metallization step may be carried out, for example, by physical vapor deposition (PVD), by sputtering, or by inkjet deposition.

For PVD or sputter deposition, a protective element 950 may locally cover part 910 (FIGS. 8 and 9). Protective element 950 may be a liner or a mechanical part. For this purpose, protective element 950 is placed on part 910 so as to partially cover it (view B of FIGS. 8 and 9). The deposition may be performed all over both the protective element 950 and the portion of part 910 not covered by protective element 950 (view C of FIGS. 8 and 9). Once the deposition has been performed, protective element 950 is removed (view D of FIGS. 8 and 9). Parts 900 having their side walls partially plated are thus obtained (view E of FIGS. 8 and 9 and 10).

For inkjet deposition, the deposition may be performed locally (view B of FIG. 10). It is not necessary to have a mask covering part 910 during the metallization.

The thickness of coating 920 may range from a few nanometers to several tens of micrometers.

Coating 920 may, for example, be made of one of the following metals or alloys: Ni, Ag, Au, Ti, Ta, TiW, Al, AlCu, AgNi, Pt, etc.

As an illustration, FIG. 7 shows the dimensions of an oblong hole (dimensions 'a') as a function of the cut-off frequency for air and for different parts made of dielectric materials. Dimensions 'b' are fixed, that is, 1.1 mm or 0.55 mm.

For a 60-Hz frequency, dimension 'a' is approximately 2.5 mm for air, 1.5 mm for FR4, and 1.0 mm for glass.

The dimensions of the waveguide can be decreased when the dielectric permittivity of the material in the through hole increases. For example, with a glass part, the dimension 'a' of the oblong hole can be decreased by 50% as compared with a medium made of air.

Various embodiments and variants have been described. Those skilled in the art will understand that certain features of these various embodiments and variants may be combined, and other variants will occur to those skilled in the art.

Finally, the practical implementation of the described embodiments and variants is within the abilities of those skilled in the art based on the functional indications given hereabove.

1. A radio frequency device, comprising:
a radio frequency (RF) chip mounted on a first main surface of a laminated substrate comprising a vertical RF feedthrough from the first main surface to a second main surface;
a plated part bonded to the second main surface of the substrate opposite the vertical RF feedthrough;
wherein the plated part comprises an element made of a dielectric material having side walls at least partially covered by a coating made of an electrically-conductive material; and
wherein the plated part as bonded to the second main surface is configured to be positioned opposite, and at least partially extending into, a through hole provided in a printed circuit board to which the laminated substrate is to be mounted.

2. The device according to claim 1, wherein an upper surface of the element of the plated part is bonded to the second main surface of the laminated substrate by a layer of adhesive.

3. The device according to claim 1, wherein the dielectric material has a dielectric permittivity greater than or equal to 2 and smaller than 10.

4. The device according to claim 1, wherein the dielectric material is glass.

5. The device according to claim 1, wherein the coating of the plated part is made of metal or of a metal alloy.

6. The device according to claim 1, wherein a lower surface of the element of the plated part is positioned between a first surface and a second surface of the printed circuit board, with the plated part being partially inserted into the through hole.

7. The device according to claim 1, wherein the second main surface of the substrate includes an array of connection balls surrounding where the plated part is bonded to the second main surface of the substrate.

8. The device according to claim 1, wherein the through hole is a plated through hole having a plating on sidewalls of the through hole.

9. A system for transmitting/receiving a radio frequency signal, comprising:
a printed circuit board having a first surface and a second surface opposite the first surface and further having a through hole extending between the first and second surfaces; and
a radio frequency device comprising:
a radio frequency (RF) chip mounted on a first main surface of a laminated substrate comprising a vertical RF feedthrough from the first main surface to a second main surface;
a plated part bonded to the second main surface of the substrate opposite the vertical RF feedthrough;
wherein the plated part comprises an element made of a dielectric material having side walls at least partially covered by a coating made of an electrically-conductive material; and
wherein the laminated substrate is mounted to the first surface of the printed circuit board with the plated part positioned opposite, and at least partially extending into, the through hole.

10. The system according to claim 9, further comprising an antenna module arranged on the second surface of the printed circuit board and coupled to the radio frequency device by means of the through hole of the printed circuit board.

11. The system according to claim 9, wherein the through hole is an oblong hole having a largest dimension in a range from 1 mm to 3 mm and a smallest dimension in a range from 0.4 mm to 1.5 mm.

12. The system according to claim 9, further comprising a layer of electrically-insulating polymer arranged between the laminated substrate and the printed circuit board around the plated part.

13. The system according to claim 12, wherein the second main surface of the substrate includes an array of connection balls surrounding where the plated part is bonded to the second main surface of the substrate, and wherein the layer of electrically-insulating polymer encapsulates the array of connection balls.

14. The system according to claim 9, wherein the through hole is filled with an electrically-insulating material, for example an epoxy resin.

15. The system according to claim 9, wherein sidewalls of the through hole are plated.

16. The system according to claim 9, wherein the radio frequency device is assembled by soldering on the first surface of the printed circuit board.
